(19) United States
(12) Patent Application Publication
(10) Pub. No.: US 2024/0332895 A1
(43) Pub. Date: Oct. 3, 2024

(54) LIGHT SOURCE DEVICE AND ELECTRONIC APPARATUS

(71) Applicant: SONY GROUP CORPORATION, TOKYO (JP)

(72) Inventors: TOMOHIRO MAKINO, TOKYO (JP); SUSUMU SEINO, TOKYO (JP)

(21) Appl. No.: 18/577,718

(22) PCT Filed: Mar. 16, 2022
(86) PCT No.: PCT/JP2022/011867

§ 371 Date: Jan. 9, 2024

(30) Foreign Application Priority Data
Jul. 20, 2021 (JP) 2021-119675

(51) Int. Cl. H01S 5/0683; H01S 5/02251; H01S 5/183; H05B 47/105

(52) U.S. Cl. CPC H01S 5/0683; H01S 5/02251; H05B 47/105; H01S 5/183

(57) ABSTRACT

A light source device according to an embodiment of the present disclosure includes a first light source section that outputs first laser light for drawing, and a second light source section that is provided adjacent to the first light source section and outputs second laser light for monitoring. The light source device further includes a light receiver that receives the second laser light, and a controller that performs light emission control on the first light source section on the basis of a detection signal from the light receiver.

### TECHNICAL FIELD

The present disclosure relates to a light source device and an electronic apparatus.

### BACKGROUND ART

As a light source for an AR (Augmented Reality) eyewear or a projector, a technique of multiplexing pieces of laser light of three colors, RGB, through an optical waveguide has been studied. Further, as a light source of an AR eyewear, considerations on VCSEL (surface-emitting laser) have been started as a low-power-consuming and eye-safe light source. Combination of these two techniques makes it possible to achieve a low-power-consuming and ultra-small RGB light source.

### CITATION LIST

### Patent Literature

PTL 1: Japanese Unexamined Patent Application Publication No. 2007-25256 PTL 2: Japanese Unexamined Patent Application Publication No. 2006-208794

### SUMMARY OF THE INVENTION

Incidentally, in order to control power of a light source, it is conceivable to monitor light-emitting power of the light source and control a driving current in accordance with a change in the light-emitting power. The light-emitting power is generally monitored by branching light outputted from the light source (see, for example, Patent Literatures 1 and 2). However, in such a case, output power for drawing is reduced. Accordingly, it is desirable to provide a light source device and an electronic apparatus that make it possible to monitor light-emitting power of a light source without reducing output power for drawing.

A light source device according to a first embodiment of the present disclosure includes a first light source section that outputs first laser light for drawing, and a second light source section that is provided adjacent to the first light source section and outputs second laser light for monitoring. The light source device further includes a light receiver that receives the second laser light, and a controller that performs light emission control on the first light source section on the basis of a detection signal from the light receiver.

An electronic apparatus according to a second embodiment of the present disclosure includes the light source device according to the first embodiment of the present disclosure.

In the light source device according to the first embodiment of the present disclosure and the electronic apparatus according to the second embodiment of the present disclosure, the second light source section that outputs the laser light for monitoring is provided adjacent to the first light source section that outputs the first laser light for drawing. This makes it possible to receive the second laser light by the light receiver, and to perform the light emission control on the first light source section on the basis of the detection signal from the light receiver.

A light source device according to a third embodiment of the present disclosure includes: first light source sections that respectively output pieces of first laser light for drawing having respective light emission wavelengths different from each other; and second light source sections that are each provided adjacent to corresponding one of the first light source sections, and respectively output pieces of second laser light for monitoring having respective wavelengths different from each other. The light source device further includes a light receiver that receives the pieces of second laser light, and a controller that performs light emission control on the first light source sections on the basis of a detection signal from the light receiver.

An electronic apparatus according to a fourth embodiment of the present disclosure includes the light source device according to the third embodiment of the present disclosure.

In the light source device according to the third embodiment of the present disclosure and the electronic apparatus according to the fourth embodiment of the present disclosure, the second light source sections that respectively output pieces of second laser light for monitoring having respective wavelengths different from each other are each provided adjacent to corresponding one of the first light source sections that respectively output pieces of first laser light for drawing. This makes it possible to receive the pieces of second laser light by the light receiver, and to perform the light emission control on the first light source section on the basis of the detection signal from the light receiver.

### BRIEF DESCRIPTION OF DRAWINGS

FIG. 1 is a diagram illustrating a schematic configuration example of a light source device according to an embodiment of the present disclosure.

FIG. 2 is a diagram illustrating an internal configuration example of an optical waveguide section of FIG. 1.

FIG. 3 is a diagram illustrating an example of a drive waveform of a light source of FIG. 1.

FIG. 4 is a diagram illustrating an example of the drive waveform of the light source of FIG. 1.

FIG. 5 is a diagram illustrating an example of an I-L characteristic of the light source of FIG. 1.

FIG. 6 is a diagram illustrating an example of the I-L characteristic of the light source of FIG. 1.

FIG. 7 is a diagram illustrating a modification example of the light source device of FIG. 1.

FIG. 8 is a diagram illustrating an internal configuration example of an optical waveguide section of FIG. 7.

FIG. 9 is a diagram illustrating an example of the drive waveform of the light source of FIG. 1.

FIG. 10 is a diagram illustrating an internal configuration example of the optical waveguide section of FIG. 2.

FIG. 11 is a diagram illustrating an internal configuration example of the optical waveguide section of FIG. 8.

FIG. 12 is a diagram illustrating an internal configuration example of the optical waveguide section of FIG. 2.

FIG. 13 is a diagram illustrating an internal configuration example of the optical waveguide section of FIG. 8.

FIG. 14 is a diagram illustrating an application example of the light source device.

### MODES FOR CARRYING OUT THE INVENTION

In the following, description is given in detail of embodiments of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.

### 1. Embodiment

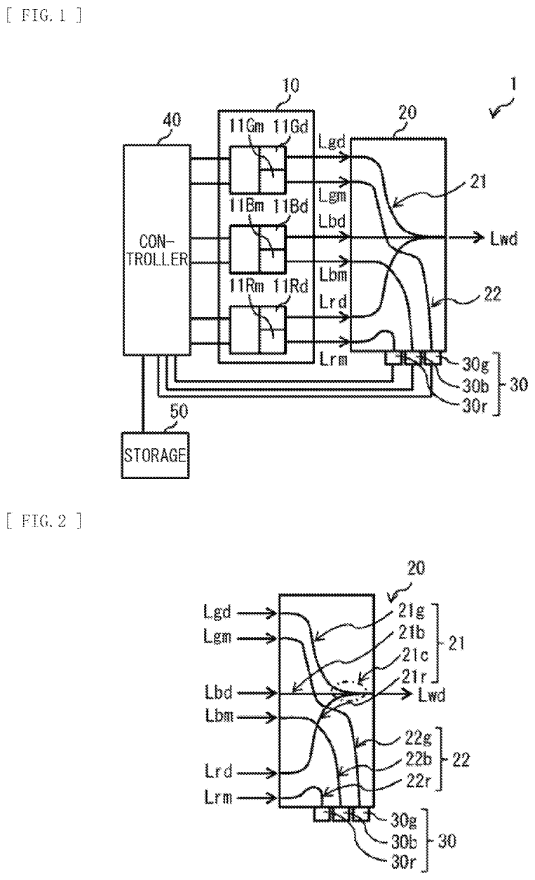

An example in which light sources are provided separately for drawing and for monitoring and optical waveguides are provided separately for drawing and for monitoring (FIGS. 1 to 6)

### 2. Modification Examples

Modification Example A: an example in which multiple light sources for drawing are provided for each color (FIG. 7)

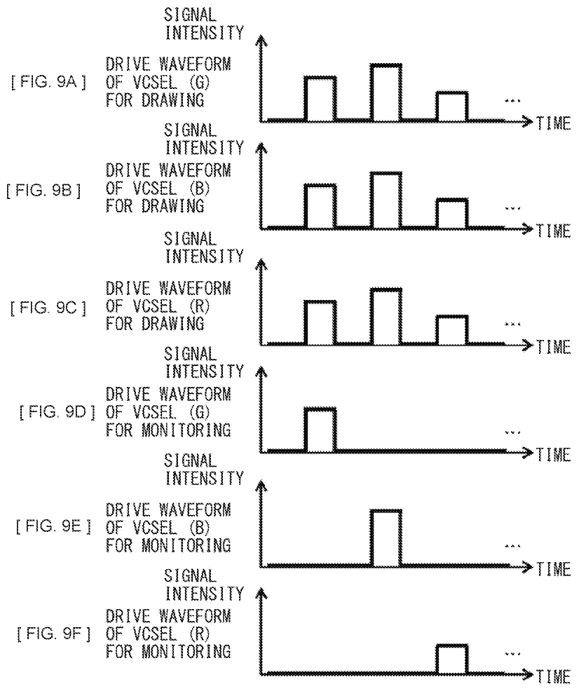

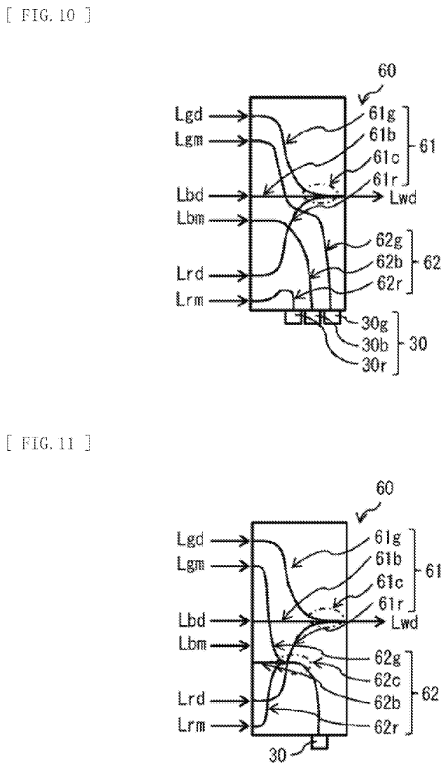

Modification Example B: an example in which optical waveguides for monitoring are combined (FIGS. 8 and 9)

Modification Example C: an example in which an optical fiber is used for an optical waveguide (FIGS. 10 and 11)

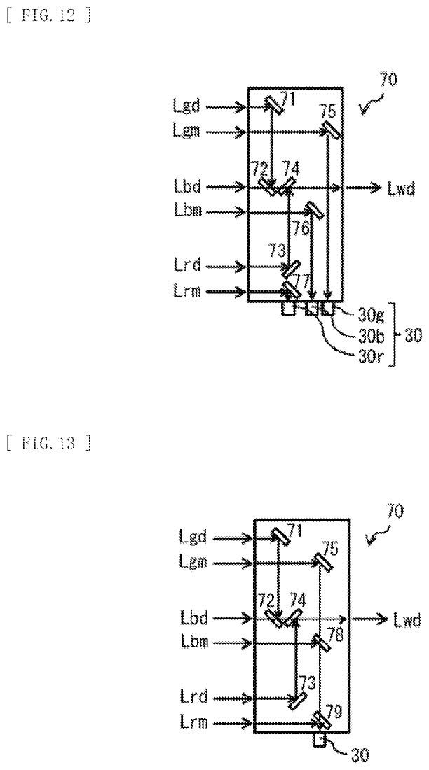

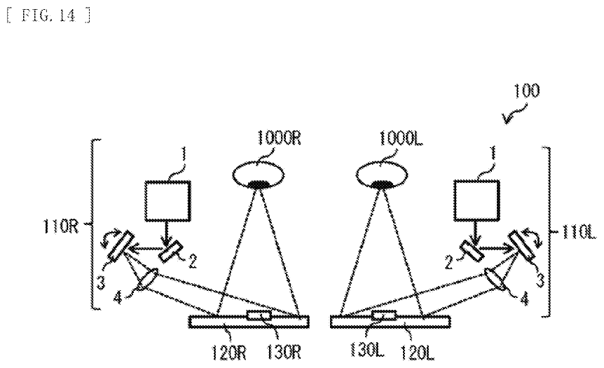

Modification Example D: an example in which a mirror is used for an optical waveguide (FIGS. 12 and 13)

### 3. Application Example

An example in which a light source device is applied to eyeglasses (FIG. 14)

### 1. Embodiment

### [Configuration]

A light source device 1 according to an embodiment of the present disclosure will be described. FIG. 1 illustrates a schematic configuration example of the light source device 1. The light source device 1 is preferably used as an AR eyewear or a light source of a projector. The light source device 1 includes a light source section 10, an optical waveguide section 20, a light receiver 30, a controller 40, and a storage 50.

The light source section 10 includes multiple light source sections 11Gd, 11Bd, and 11Rd for drawing and multiple light source sections 11Gm, 11Bm, and 11Rm for monitoring. The light source sections 11Gd, 11Bd, and 11Rd respectively output pieces of laser light Lgd, Lbd, and Lrd for drawing having respective light emission wavelengths different from each other. The light source sections 11Gm, 11Bm, and 11Rm respectively output pieces of laser light Lgm, Lbm, and Lrm for monitoring having respective light emission wavelength different from each other. The multiple light source sections 11Gm, 11Bm, and 11Rm for monitoring have light emission wavelengths equal to light emission wavelengths of the light source sections 11Gm, 11Bm, and 11Rm for drawing.

The light source section 11Gd outputs, for example, the green laser light Lgd (for example, a waveband of higher than or equal to 500 nm and lower than or equal to 550 nm). The light source section 11Gm outputs, for example, the green laser light Lgm. The light source sections 11Gd and 11Gm include respective surface-emitting semiconductor light-emitting elements (VCSELs) provided on a common crystal growth substrate and having a common light emission wavelength. The light source sections 11Gd and 11Gm include, for example, a GaInN-based semiconductor material. The light source section 11Gm is provided adjacent to the light source section 11Gd, and includes the same material as and has the same layer structure as the light source section 11Gd. Accordingly, a similarity between a light emission characteristic of the light source section 11Gm and a light emission characteristic of the light source section 11Gd is high.

The light source section 11Bd outputs, for example, the blue laser light Lbd (for example, a waveband of higher than or equal to 430 nm and lower than or equal to 500 nm). The light source section 11Bm outputs, for example, the blue laser light Lbm. The light source sections 11Bd and 11Bm include respective surface-emitting semiconductor light-emitting elements (VCSELs) provided on a common crystal growth substrate and having a common light emission wavelength. The light source sections 11Bd and 11Bm include, for example, a GaInN-based semiconductor material. The light source section 11Bm is provided adjacent to the light source section 11Bd, and includes the same material as and has the same layer structure as the light source section 11Bd. Accordingly, a similarity between a light emission characteristic of the light source section 11Bm and a light emission characteristic of the light source section 11Bd is high.

The light source section 11Rd outputs, for example, the red laser light Lrd (for example, a waveband of higher than or equal to 610 nm and lower than or equal to 780 nm). The light source section 11Rm outputs, for example, the red laser light Lrm. The light source sections 11Rd and 11Rm include respective surface-emitting semiconductor light-emitting elements (VCSELs) provided on a common crystal growth substrate and having a common light emission wavelength. The light source sections 11Rd and 11Rm include, for example, a GaInN-based semiconductor material. The light source section 11Rm is provided adjacent to the light source section 11Rd, and includes the same material as and has the same layer structure as the light source section 11Rd. Accordingly, a similarity between a light emission characteristic of the light source section 11Rm and a light emission characteristic of the light source section 11Rd is high.

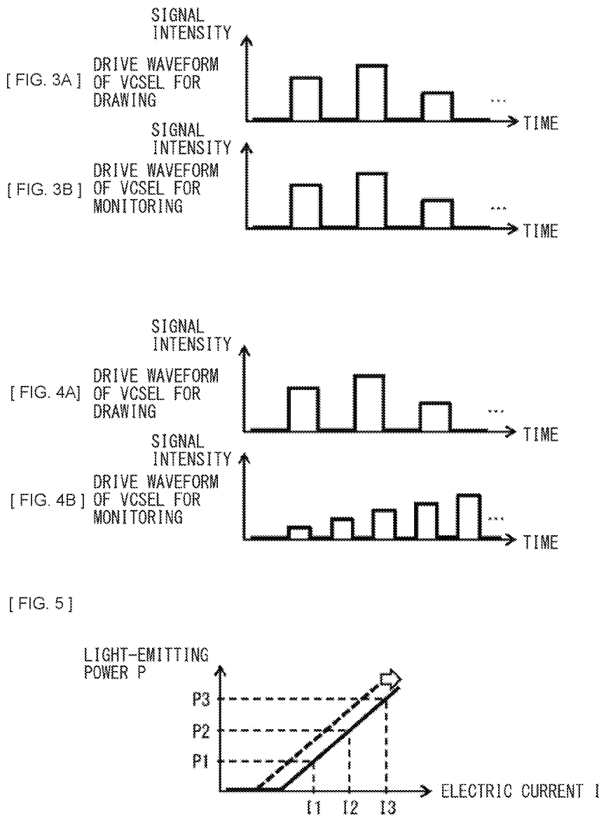

FIG. 2 illustrates an internal configuration example of the optical waveguide section 20. The optical waveguide section 20 includes an optical waveguide 21 and an optical waveguide 22. The optical waveguides 21 and 22 are each, for example, a planar lightwave circuit (PLC), and each include, for example, a core having a high refractive index, and a clad surrounding the core and having a refractive index lower than that of the core.

The optical waveguide 21 guides the pieces of laser light Lgd, Lbd, and Lbd for drawing from the light source sections 11Gd, 11Bd, and 11Rd to an outside. The optical waveguide 21 includes: optical waveguides 21g, 21b, and 21r respectively provided for the light source sections 11Gd, 11Bd, and 11Rd; and a multiplexer 21c that combines the optical waveguides 21g, 21b, and 21r. The optical waveguide 21g guides the laser light Lgd for drawing from the light source section 11Gd to the multiplexer 21c. The optical waveguide 21b guides the laser light Lbd for drawing from the light source section 11Bd to the multiplexer 21c. The optical waveguide 21r guides the laser light Lrd for drawing from the light source section 11Rd to the multiplexer 21c. The multiplexer 21c is, for example, an optical component that combines the optical waveguides 21g, 21b, and 21r. The multiplexer 21c, for example, multiplexes the pieces of laser light Lgd, Lbd, and Lrd respectively transmitted through the optical waveguides 21g, 21b, and 21r, and guides the multiplexed light to one optical waveguide.

The optical waveguide 22 is an optical waveguide separate from the optical waveguide 21. The optical waveguide 22 guides the pieces of laser light Lgm, Lbm, and Lbm for monitoring from the light source sections 11Gm, 11Bm, and 11Rm to the light receiver 30. The optical waveguide 22 includes optical waveguides 22g, 22b, and 22r respectively provided for the light source sections 11Gm, 11Bm, and 11Rm. The optical waveguide 22g guides the laser light Lgd for drawing from the light source section 11Gm to a light receiver 30g (to be described below). The optical waveguide 22b guides the laser light Lbd for drawing from the light source section 11Bm to a light receiver 30b (to be described below). The optical waveguide 22r guides the laser light Lrd for drawing from the light source section 11Rm to a light receiver 30r (to be described below).

The light receiver 30 receives the pieces of laser light Lgm, Lbm, and Lbm for monitoring. The light receiver 30 includes the light receiver 30g that receives the laser light Lgm for monitoring, the light receiver 30b that receives the laser light Lbm for monitoring, and the light receiver 30r that receives the laser light Lrm for monitoring. The light receivers 30g, 30b, and 30r each include, for example, a photodiode that photoelectrically converts light in the visible region.

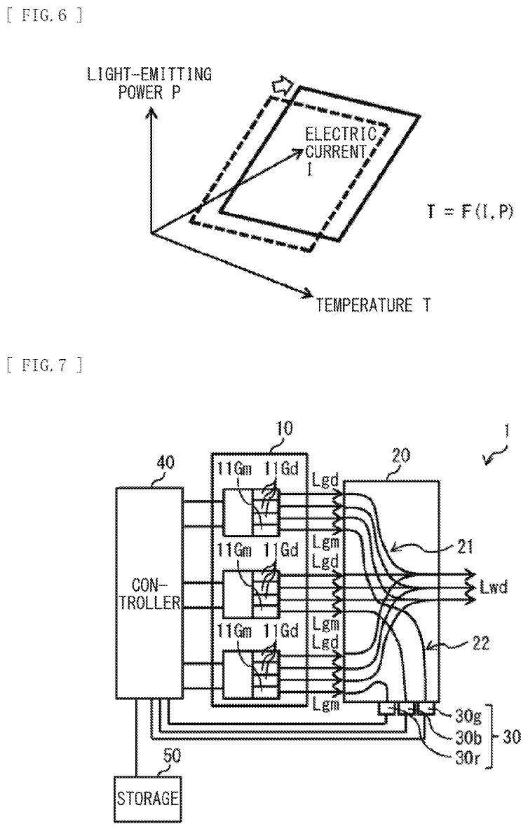

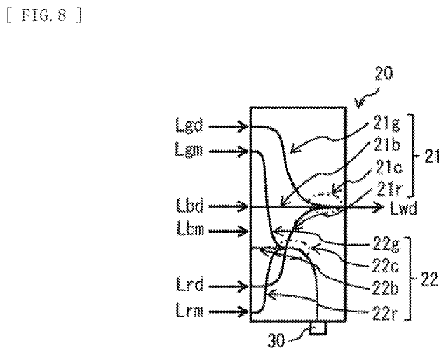

The storage 50 stores correction data to be used for control of light-emitting power of the light source sections 11Gd, 11Bd, and 11Rd. The storage 50 includes, for example, a nonvolatile memory such as a flash memory. The correction data may include, for example, I-L characteristic data (see FIG. 5) or I-L-T characteristic data (see FIG. 6), and relative error data.

The controller 40 performs light emission control on the light source sections 11Gd, 11Bd, and 11Rd on the basis of a detection signal from the light receiver 30. The controller 40 also performs light emission control on the light source sections 11Gm, 11Bm, and 11Rm. For example, as illustrated in (A) and (B) of FIG. 3, the controller 40 controls the light-emitting power of each of the light source sections 11Gd, 11Bd, and 11Rd on the basis of a detection signal obtained from the light receiver 30. The detection signal is obtained when the light emission control is performed on the light source sections 11Gd, 11Bd, and 11Rd and the light source sections 11Gm, 11Bm, and 11Rm using respective drive signals identical to each other. Hereinafter, the light emission control in such a case is referred to as first light emission control. When the first light emission control is being performed, active-layer temperature of each of the light source sections 11Gm, 11Bm, and 11Rm is approximately equal to active-layer temperature of each of the light source sections 11Gd, 11Bd, and 11Rd. Further, light-emitting power of each of the pieces of laser light Lgm, Lbm, and Lrm outputted from the light source sections 11Gm, 11Bm, and 11Rm is approximately equal to light-emitting power of each of the pieces of laser light Lgd, Lbd, and Lrd outputted from the light source sections 11Gd, 11Bd, and 11Rd.

The controller 40 measures an I-L characteristic of each of the light source sections 11Gm, 11Bm, and 11Rm when performing the first light emission control. Specifically, as illustrated in (A) and (B) of FIG. 4, when performing the first light emission control, the controller 40 temporarily applies, to the light source sections 11Gm, 11Bm, and 11Rm, a drive signal (a measurement drive signal) that is different from the drive signal to be applied to the light source sections 11Gd, 11Bd, and 11Rd, for example. The controller 40 applies the measurement drive signal to the light source sections 11Gm, 11Bm, and 11Rm, thereby obtaining a detection signal from the light receiver 30. On the basis of the thus obtained detection signal, the controller 40 derives the I-L characteristic data of each of the light source sections 11Gm, 11Bm, and 11Rm.

In FIG. 5, the I-L characteristic data stored in the storage 50 as initial data is indicated by a dashed line, and the I-L characteristic data derived by the controller 40 is indicated by a solid line. A reason why the two pieces of I-L characteristic data differ from each other is that, for example, the light source sections 11Gm, 11Bm, and 11Rm have changed due to aging.

The controller 40 may measure I-L-T characteristic data of each of the light source sections 11Gm, 11Bm, and 11Rm when performing the first light emission control. In this case, first, the controller 40 measures active-layer temperature T of each of the light source sections 11Gm, 11Bm, and 11Rm on the basis of the detection signal obtained from the light receiver 30 when performing the first light emission control. The controller 40 measures the active-layer temperature T of each of the light source sections 11Gm, 11Bm, and 11Rm using, for example, the following equation.

T=F(I, P)

I: electric current I flowing in each of the light source sections 11Gm, 11Bm, and 11Rm (a value set by the controller 40)

P: light-emitting power P of each of the light source sections 11Gm, 11Bm, and 11Rm obtained on the basis of the detection signal obtained from the light receiver 30

F(I, P): a mathematical function using the electric current I (a value set by the controller 40) and the light-emitting power P as parameters

Thereafter, the controller 40 derives the I-L-T characteristic data of each of the light source sections 11Gm, 11Bm, and 11Rm on the basis of: the obtained active-layer temperature T; and the detection signal obtained from the light receiver 30 by applying the measurement drive signal to the light source sections 11Gm, 11Bm, and 11Rm. That is, the controller 40 derives the I-L-T characteristic data of each of the light source sections 11Gm, 11Bm, and 11Rm on the basis of: the detection signal obtained from the light receiver 30 by the first light emission control; and the detection signal obtained from the light receiver 30 by applying the measurement drive signal to the light source sections 11Gm, 11Bm, and 11Rm.

In FIG. 6, the I-L-T characteristic data stored in the storage 50 as initial data is indicated by a dashed line, and the I-L-T characteristic data derived by the controller 40 is indicated by a solid line. A reason why the two pieces of I-L characteristic data differ from each other is that, for example, the light source sections 11Gm, 11Bm, and 11Rm have changed due to aging.

### [Effects]

Next, effects of the light source device 1 according to the present embodiment will be described.

As a light source for an AR eyewear or a projector, a technique of multiplexing pieces of laser light of three colors, RGB, through an optical waveguide has recently been studied. Further, as a light source of an AR eyewear, considerations on VCSEL have been started as a low-power-consuming and eye-safe light source. Combination of these two techniques makes it possible to achieve a low-power-consuming and ultra-small RGB light source.

Incidentally, in order to control power of a light source, it is conceivable to monitor light-emitting power of the light source and control a driving current in accordance with a change in the light-emitting power. The light-emitting power is generally monitored by branching light outputted from the light source.

For example, in the invention disclosed in PTL 1, array optical waveguides coupled to light-emitting elements each include a main waveguide and a branch waveguide in each waveguide, and the branch waveguides combine together to configure a coupled waveguide. Light outputted from the coupled waveguide is received by one light receiving element. Further, for example, the invention disclosed in PTL 2 provides a light-emitting element, and an optical waveguide that guides the light outputted from the light-emitting element. A notch is provided in a portion of the optical waveguide, and light leaked from the notch is monitored by the light receiving element.

However, in each of the inventions disclosed in PTLs 1 and 2, multiple light-emitting elements output light simultaneously during image drawing, and it is not possible to control light-emitting power for each light-emitting element. Further, some of the light outputted from the light-emitting element is branched to the light receiving element, and thus the light-emitting power of the light used for image drawing is lowered. Further, in a case where light emission for light emission control is performed separately from light emission for drawing, a user can visually recognize the light emission for the light emission control.

In contrast, the present embodiment provides the multiple light source sections 11Gm, 11Bm, and 11Rm for monitoring each provided adjacent to corresponding one of the multiple light source sections 11Gd, 11Bd, and 11Rd for drawing. Thus, it is possible to receive the multiple pieces of laser light Lgm, Lbm, and Lrm for monitoring by the light receiver 30, and to perform the light emission control on the multiple light source sections 11Gd, 11Bd, and 11Rd for drawing on the basis of the detection signal from the light receiver 30. As a result, it is possible to monitor the light-emitting power of each of the light source sections 11Gd, 11Bd, and 11Rd without reducing the output power for drawing.

Further, in the present embodiment, the light source section 11Gd for drawing and the light source section 11Gm for monitoring include the respective semiconductor light-emitting elements provided on the common semiconductor substrate. Further, the light source section 11Bd for drawing and the light source section 11Bm for monitoring include the respective semiconductor light-emitting elements provided on the common semiconductor substrate. The light source section 11Rd for drawing and the light source section 11Rm for monitoring include the respective semiconductor light-emitting elements provided on the common semiconductor substrate. This increases the similarity between the light emission characteristic of the light source section 11Gm for monitoring and the light emission characteristic of the light source section 11Gd for drawing. Further, this increases the similarity between the light emission characteristic of the light source section 11Bm for monitoring and the light emission characteristic of the light source section 11Bd for drawing. Further, this increases a similarity between a light emission characteristic of each of the multiple pieces of laser light Lgm, Lbm, and Lrm for monitoring and the light emission characteristic of the light source section 11Rd for drawing. As a result, it is possible to store a relative error between the light emission characteristic of the light source section 11Gm for monitoring and the light emission characteristic of each of the multiple light source sections 11Gd, 11Bd, and 11Rd for drawing in the storage 50 in advance as the correction data, and to use the relative error for the light emission control.

Further, in the present embodiment, the light-emitting power of each of the multiple light source sections 11Gd, 11Bd, and 11Rd for drawing is controlled on the basis of the detection signal obtained from the light receiver 30 when the first light emission control is performed. Here, when the first light emission control is performed, the active-layer temperature of each of the light source sections 11Gm, 11Bm, and 11Rm is approximately equal to the active-layer temperature of each of the light source sections 11Gd, 11Bd, and 11Rd. Further, the light-emitting power of each of the pieces of laser light Lgm, Lbm, and Lrm outputted from the light source sections 11Gm, 11Bm, and 11Rm is approximately equal to the light-emitting power of each of the pieces of laser light Lgd, Lbd, and Lrd outputted from the light source sections 11Gd, 11Bd, and 11Rd. It is therefore possible to accurately control the light-emitting power of each of the multiple light source sections 11Gd, 11Bd, and 11Rd for drawing on the basis of the detection signal obtained by the light receiver 30 receiving the multiple pieces of laser light Lgm, Lbm, and Lrm for monitoring.

Further, in the present embodiment, the light-emitting power of each of the multiple light source sections 11Gm, 11Bm, and 11Rm for monitoring is controlled on the basis of: the detection signal (a second detection signal) obtained from the light receiver 30 when the drive signal that is different from the drive signal to be applied to the multiple light source sections 11Gd, 11Bd, and 11Rd for drawing is applied to the multiple light source sections 11Gm, 11Bm, and 11Rm for monitoring; and the detection signal obtained by the first light emission control. Here, it is possible to derive the active-layer temperature T of each of the multiple light source sections 11Gm, 11Bm, and 11Rm for monitoring from the second detection signal, and also to control the light-emitting power of each of the multiple light source sections 11Gm, 11Bm, and 11Rm for monitoring on the basis of the I-L characteristic data corresponding to the derived active-layer temperature T. As a result, it is possible to control with high accuracy the light-emitting power of each of the multiple light source sections 11Gd, 11Bd, and 11Rd for drawing.

### 2. Modification Examples

Next, modification examples of the light source device 1 according to the above-described embodiment will be described.

### Modification Example A

In the above-described embodiment, for example, as illustrated in FIG. 7, multiple light source sections 11Gd that each output the green laser light Lgd may be provided. Further, in the above-described embodiment, for example, as illustrated in FIG. 7, multiple light source sections 11Bd that each output the blue laser light Lbd may be provided. Further, in the above-described embodiment, for example, as illustrated in FIG. 7, multiple light source sections 11Rd that each output the red laser light Lrd may be provided.

### Modification Example B

In the embodiment and the modification example thereof described above, for example, as illustrated in FIG. 8, the optical waveguide 22 may include: the optical waveguides 22g, 22b, and 22r; and a multiplexer 22c that combines the optical waveguides 22g, 22b, and 22r. In this case, the multiplexer 22c is, for example, an optical component that combines the optical waveguides 22g, 22b, and 22r. The multiplexer 22c, for example, multiplexes the pieces of laser light Lgm, Lbm, and Lrm respectively transmitted through the optical waveguides 22g, 22b, and 22r and guides the multiplexed light to one optical waveguide. The multiplexed light enters one light receiver 30. It is therefore possible in the present modification example to reduce the number of light receivers 30 as compared with the above-described embodiment.

Here, for example, as illustrated in FIG. 9, it is possible for the controller 30 to perform the light emission control on each of the light source sections 11Gm, 11Bm, and 11Rm for monitoring by sequentially causing the light source sections 11Gm, 11Bm, and 11Rm for monitoring to output light in time-series order.

### Modification Example C

In the embodiment and the modification examples thereof described above, for example, as illustrated in FIGS. 10 and 11, an optical waveguide section 60 may be provided instead of the optical waveguide section 20. The optical waveguide section 60 corresponds to the optical waveguide section 20 in which all the optical waveguides are replaced with optical fibers. As described above, in a case where the optical fibers are used also, it is possible to accurately control the light-emitting power of each of the multiple light source sections 11Gd, 11Bd, and 11Rd for drawing as with the above-described embodiment.

### Modification Example D

In the embodiment and the modification examples thereof described above, for example, as illustrated in FIGS. 12 and 13, an optical waveguide section 70 may be provided instead of the optical waveguide section 20. The optical waveguide section 70 corresponds to, for example, as illustrated in FIG. 12, the optical waveguide section 20 in which: the optical waveguides are omitted; reflection mirrors 71 and 73 and dichroic mirrors 72 and 74 are provided in optical paths of the pieces of laser light Lgd, Lbd, and Lrd; and reflection mirrors 75, 76, and 77 are provided in optical paths of the pieces of laser light Lgm, Lbm, and Lrm. Further, the optical waveguide section 70 corresponds to, for example, as illustrated in FIG. 13, the optical waveguide section 20 in which: the optical waveguides are omitted; the reflection mirrors 71 and 73 and the dichroic mirrors 72 and 74 are provided in the optical paths of the pieces of laser light Lgd, Lbd, and Lrd; and the reflection mirror 75 and dichroic mirrors 78 and 79 are provided in the optical paths of the pieces of laser light Lgm, Lbm, and Lrm. As described above, in a case where the reflection mirrors and the dichroic mirrors are used also, it is possible to accurately control the light-emitting power of each of the multiple light source sections 11Gd, 11Bd, and 11Rd for drawing as with the above-described embodiment.

### 3. Application Example

Next, an application example of the light source device 1 according to the embodiment and the modification examples thereof described above will be described.

FIG. 14 illustrates a schematic configuration example of eyeglasses 100 including the light source device 1 according to the embodiment and the modification examples thereof described above. The eyeglasses 100 include an image projector 110R for a right eye, a combiner 120R for the right eye, and an imaging section 130R for the right eye. The eyeglasses 100 further include an image projector 110L for a left eye, a combiner 120L for the left eye, and an imaging section 130L for the left eye.

The image projectors 110R and 110L each includes a light source device 1(R) that outputs R (red) light, a light source device 1(G) that outputs G (green) light, a light source device 1(B) that outputs B (blue) light, and an optical waveguide 2 that multiplexes the R light, the G light, and the B light. The image projector 110R further includes a mirror 3 that reflects white light generated by the multiplexing performed by the optical waveguide 2, and a scan mirror 4 that scans biaxially a surface of the combiner 120R via a lens 5 using the white light reflected by the mirror 3. The image projector 110L further includes a mirror 3 that reflects white light generated by the multiplexing performed by the optical waveguide 2, and a scan mirror 4 that scans biaxially a surface of the combiner 120L via a lens 5 using the white light reflected by the mirror 3.

The combiner 120R diffracts light drawn on the surface of the combiner 120R by the image projector 110R and projects the light onto a retina of a right eye 1000R. The imaging section 130R performs imaging to thereby acquire image data including the right eye 1000R, and detects a position of the right eye 1000R on the basis of the acquired image data. The imaging section 130R outputs the detected position of the right eye 1000R to the image projector 110R. The image projector 110R controls the scanning of the scan mirror 4 in such a manner that the light is projected at the position of the right eye 1000R obtained from the imaging section 130R.

The combiner 120L diffracts light drawn on the surface of the combiner 120L by the image projector 110L and projects the light onto a retina of a left eye 1000L. The imaging section 130L performs imaging to thereby acquire image data including the left eye 1000L, and detects a position of the left eye 1000L on the basis of the acquired image data. The imaging section 130L outputs the detected position of the left eye 1000L to the image projector 110L. The image projector 110L controls the scanning of the scan mirror 4 in such a manner that the light is projected at the position of the left eye 1000L obtained from the imaging section 130L.

In the present application example, the light source device 1 according to the embodiment and the modification examples thereof described above is used as a light source of each of the image projectors 110R and 110L. It is therefore possible to perform light combining and light-output monitoring with an easily-achievable configuration by the image projectors 110R and 110L.

Although the disclosure is described hereinabove with reference to the example embodiment and modification examples, these embodiments are not to be construed as limiting the scope of the disclosure and may be modified in a wide variety of ways. It should be appreciated that the effects described herein are mere examples. Effects of the example embodiment and modification examples of the disclosure are not limited to those described herein. The disclosure may further include any effects other than those described herein. Further, the present disclosure may also have the following configurations.
(1)
   A light source device including:
   a first light source section that outputs first laser light for drawing;
   a second light source section that is provided adjacent to the first light source section, and outputs second laser light for monitoring;
   a light receiver that receives the second laser light; and
   a controller that performs light emission control on the first light source section on a basis of a detection signal from the light receiver.
(2)
   The light source device according to (1), in which the first light source section and the second light source section include respective semiconductor light-emitting elements provided on a common semiconductor substrate and having a common light emission wavelength.
(3)
   The light source device according to (2), in which the controller controls light-emitting power of the first light source section on a basis of a first detection signal obtained from the light receiver, the first detection signal being obtained when the light emission control is performed on the first light source section and the second light source section using respective drive signals identical to each other.
(4)
   The light source device according to (3), in which the controller controls the light-emitting power of the first light source section on a basis of a second detection signal obtained from the light receiver, the second detection signal being obtained when the controller applies, to the second light source section, a drive signal that is different from a drive signal to be applied to the first light source section.
(5)
   The light source device according to (4), further including
   a storage that stores correction data to be used for control of the light-emitting power of the first light source section, in which
   the controller controls the light-emitting power of the first light source section on a basis of the first detection signal, the second detection signal, and the correction data.
(6)
   The light source device according to any one of (1) to (5), further including:
   a first optical waveguide that guides the first laser light from the first light source section to an outside; and
   a second optical waveguide that guides the second laser light from the second light source section to the light receiver, the second optical waveguide being separate from the first optical waveguide.
(7)
   The light source device according to any one of (1) to (5), further including:
   a first optical fiber that guides the first laser light from the first light source section to an outside; and
   a second optical fiber that guides the second laser light from the second light source section to the light receiver, the second optical fiber being different from the first optical fiber.
(8)
   A light source device including:
   first light source sections that respectively output pieces of first laser light for drawing having respective light emission wavelengths different from each other;
   second light source sections that are each provided adjacent to corresponding one of the first light source sections, and respectively output pieces of second laser light for monitoring having respective wavelengths different from each other;
   a light receiver that receives the pieces of second laser light; and
   a controller that performs light emission control on the first light source sections on a basis of a detection signal from the light receiver.
(9)
   The light source device according to (8), in which
   each of the second light source sections and corresponding one of the first light source sections that have a common light emission wavelength are provided adjacent to each other, and
   the first light source section and the second light source section having the common light emission wavelength include respective semiconductor light-emitting elements provided on a common semiconductor substrate.
(10)
   The light source device according to (9), in which the controller controls light-emitting power of each of the first light source sections on a basis of a first detection signal obtained from the light receiver, the first detection signal being obtained when the light emission control is performed on each set of the first light source section and the second light source section having the common light emission wavelength using respective drive signals identical to each other.
(11)
   The light source device according to (10), in which the controller controls the light-emitting power of each of the first light source sections on a basis of a second detection signal obtained from the light receiver, the second detection signal being obtained when the controller applies, to each of the second light source sections, a drive signal that is different from a drive signal to be applied to the first light source section having the common light emission wavelength.
(12)
   The light source device according to (11), further including
   a storage that stores correction data to be used for control of the light-emitting power of each of the first light source sections, in which
   the controller controls the light-emitting power of each of the first light source sections on a basis of the first detection signal, the second detection signal, and the correction data.
(13)
   The light source device according to any one of (8) to (12), further including:
   a first optical waveguide that guides the first laser light from each of the first light source sections to an outside; and
   a second optical waveguide that guides the second laser light from each of the second light source sections to the light receiver, the second optical waveguide being separate from the first optical waveguide.
(14)
   The light source device according to (13), in which
   the first optical waveguide includes
      third optical waveguides respectively provided for the first light source sections, and
      a first multiplexer that combines the third optical waveguides,
   the second optical waveguide includes fourth optical waveguides respectively provided for the second light source sections, and
   the light receiver includes light receiving elements respectively provided for the fourth optical waveguides.
(15)
   The light source device according to (13), in which
   the first optical waveguide includes
      third optical waveguides respectively provided for the first light source sections, and
      a first multiplexer that combines the third optical waveguides, and the second optical waveguide includes
      fourth optical waveguides respectively provided for the first light source sections, and
      a second multiplexer that combines the fourth optical waveguides.
(16)
   The light source device according to (8), further including:
   a first optical fiber that guides the first laser light from each of the first light source sections to an outside; and
   a second optical fiber that guides the second laser light from each of the second light source sections to the light receiver, the second optical fiber being different from the first optical fiber.
(17)
   The light source device according to (16), in which
   the first optical fiber includes
      third optical fibers respectively provided for the first light source sections, and
      a first multiplexer that combines the third optical fibers,
   the second optical fiber includes fourth optical fibers respectively provided for the second light source sections, and
   the light receiver includes light receiving elements respectively provided for the fourth optical waveguides.
(18)
   The light source device according to (16), in which
   the first optical fiber includes
      third optical fibers respectively provided for the first light source sections, and
      a first multiplexer that combines the third optical fibers, and
   the second optical fiber includes
      fourth optical fibers respectively provided for the second light source sections, and
      a second multiplexer that combines the fourth optical fibers.
(19)
   An electronic apparatus including
   a light source device, in which
   the light source device includes
      a first light source section that outputs first laser light for drawing,
      a second light source section that is provided adjacent to the first light source section, and outputs second laser light for monitoring,
      a light receiver that receives the second laser light, and
      a controller that performs light emission control on the first light source section on a basis of a detection signal from the light receiver.
(20)
   An electronic apparatus including
   a light source device, in which
   the light source device includes
      first light source sections that respectively output pieces of first laser light for drawing having respective wavelengths different from each other,
      second light source sections that are each provided adjacent to corresponding one of the first light source sections, and respectively output pieces of second laser light for monitoring having respective wavelengths different from each other,
      a light receiver that receives the pieces of second laser light, and
      a controller that performs light emission control on the first light source sections on a basis of a detection signal from the light receiver.

In the light source device according to the first embodiment of the present disclosure and the electronic apparatus according to the second embodiment of the present disclosure, the second light source section that outputs the laser light for monitoring is provided adjacent to the first light source section that outputs the first laser light for drawing. This makes it possible to receive the second laser light by the light receiver, and to perform the light emission control on the first light source section on the basis of the detection signal from the light receiver. As a result, it is possible to monitor the light-emitting power of the light source without reducing the output power for drawing.

In the light source device according to the third embodiment of the present disclosure and the electronic apparatus according to the fourth embodiment of the present disclosure, the second light source sections that respectively output pieces of second laser light for monitoring having respective wavelengths different from each other are each provided adjacent to corresponding one of the first light source sections that respectively output pieces of first laser light for drawing. This makes it possible to receive the pieces of second laser light by the light receiver, and to perform the light emission control on the first light source section on the basis of the detection signal from the light receiver. As a result, it is possible to monitor the light-emitting power of the light source without reducing the output power for drawing. It is to be noted that the effects of the present disclosure are not necessarily limited to the effects described herein, and may be any effects described herein.

This application claims the benefit of Japanese Priority Patent Application JP2021-119675 filed with the Japan Patent Office on Jul. 20, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light source device comprising:
a first light source section that outputs first laser light for drawing;
a second light source section that is provided adjacent to the first light source section, and outputs second laser light for monitoring;
a light receiver that receives the second laser light; and
a controller that performs light emission control on the first light source section on a basis of a detection signal from the light receiver.

2. The light source device according to claim 1, wherein the first light source section and the second light source section comprise respective semiconductor light-emitting elements provided on a common semiconductor substrate and having a common light emission wavelength.

3. The light source device according to claim 2, wherein the controller controls light-emitting power of the first light source section on a basis of a first detection signal obtained from the light receiver, the first detection signal being obtained when the light emission control is performed on the first light source section and the second light source section using respective drive signals identical to each other.

4. The light source device according to claim 3, wherein the controller controls the light-emitting power of the first light source section on a basis of a second detection signal obtained from the light receiver, the second detection signal being obtained when the controller applies, to the second light source section, a drive signal that is different from a drive signal to be applied to the first light source section.

5. The light source device according to claim 4, further comprising
a storage that stores correction data to be used for control of the light-emitting power of the first light source section, wherein
the controller controls the light-emitting power of the first light source section on a basis of the first detection signal, the second detection signal, and the correction data.

6. The light source device according to claim 1, further comprising:
a first optical waveguide that guides the first laser light from the first light source section to an outside; and
a second optical waveguide that guides the second laser light from the second light source section to the light receiver, the second optical waveguide being separate from the first optical waveguide.

7. The light source device according to claim 1, further comprising:
a first optical fiber that guides the first laser light from the first light source section to an outside; and
a second optical fiber that guides the second laser light from the second light source section to the light receiver, the second optical fiber being different from the first optical fiber.

8. A light source device comprising:
first light source sections that respectively output pieces of first laser light for drawing having respective light emission wavelengths different from each other;
second light source sections that are each provided adjacent to corresponding one of the first light source sections, and respectively output pieces of second laser light for monitoring having respective wavelengths different from each other;
a light receiver that receives the pieces of second laser light; and
a controller that performs light emission control on the first light source sections on a basis of a detection signal from the light receiver.

9. The light source device according to claim 8, wherein
each of the second light source sections and corresponding one of the first light source sections that have a common light emission wavelength are provided adjacent to each other, and
the first light source section and the second light source section having the common light emission wavelength comprise respective semiconductor light-emitting elements provided on a common semiconductor substrate.

10. The light source device according to claim 9, wherein the controller controls light-emitting power of each of the first light source sections on a basis of a first detection signal obtained from the light receiver, the first detection signal being obtained when the light emission control is performed on each set of the first light source section and the second light source section having the common light emission wavelength using respective drive signals identical to each other.

11. The light source device according to claim 10, wherein the controller controls the light-emitting power of each of the first light source sections on a basis of a second detection signal obtained from the light receiver, the second detection signal being obtained when the controller applies, to each of the second light source sections, a drive signal that is different from a drive signal to be applied to the first light source section having the common light emission wavelength.

12. The light source device according to claim 11, further comprising
a storage that stores correction data to be used for control of the light-emitting power of each of the first light source sections, wherein
the controller controls the light-emitting power of each of the first light source sections on a basis of the first detection signal, the second detection signal, and the correction data.

13. The light source device according to claim 8, further comprising:
a first optical waveguide that guides the first laser light from each of the first light source sections to an outside; and
a second optical waveguide that guides the second laser light from each of the second light source sections to the light receiver, the second optical waveguide being separate from the first optical waveguide.

14. The light source device according to claim 13, wherein
the first optical waveguide includes
third optical waveguides respectively provided for the first light source sections, and
a first multiplexer that combines the third optical waveguides,
the second optical waveguide includes fourth optical waveguides respectively provided for the second light source sections, and
the light receiver includes light receiving elements respectively provided for the fourth optical waveguides.

15. The light source device according to claim 13, wherein
the first optical waveguide includes
third optical waveguides respectively provided for the first light source sections, and
a first multiplexer that combines the third optical waveguides, and
the second optical waveguide includes
fourth optical waveguides respectively provided for the first light source sections, and
a second multiplexer that combines the fourth optical waveguides.

16. The light source device according to claim 8, further comprising:
a first optical fiber that guides the first laser light from each of the first light source sections to an outside; and
a second optical fiber that guides the second laser light from each of the second light source sections to the light receiver, the second optical fiber being different from the first optical fiber.

17. The light source device according to claim 16, wherein
the first optical fiber includes
third optical fibers respectively provided for the first light source sections, and
a first multiplexer that combines the third optical fibers,
the second optical fiber includes fourth optical fibers respectively provided for the second light source sections, and
the light receiver includes light receiving elements respectively provided for the fourth optical waveguides.

18. The light source device according to claim 16, wherein
the first optical fiber includes
third optical fibers respectively provided for the first light source sections, and
a first multiplexer that combines the third optical fibers, and the second optical fiber includes
fourth optical fibers respectively provided for the second light source sections, and
a second multiplexer that combines the fourth optical fibers.

19. An electronic apparatus comprising
a light source device, wherein
the light source device includes
a first light source section that outputs first laser light for drawing,
a second light source section that is provided adjacent to the first light source section, and outputs second laser light for monitoring,
a light receiver that receives the second laser light, and
a controller that performs light emission control on the first light source section on a basis of a detection signal from the light receiver.

20. An electronic apparatus comprising
a light source device, wherein
the light source device includes
first light source sections that respectively output pieces of first laser light for drawing having respective wavelengths different from each other,
second light source sections that are each provided adjacent to corresponding one of the first light source sections, and respectively output pieces of second laser light for monitoring having respective wavelengths different from each other,
a light receiver that receives the pieces of second laser light, and
a controller that performs light emission control on the first light source sections on a basis of a detection signal from the light receiver.
